(19) United States
(12) Patent Application Publication
(10) Pub. No.: US 2018/0216959 A1
(43) Pub. Date: Aug. 2, 2018

(54) A Combined Motion Capture System

(71) Applicant: Beijing Noitom Technology Ltd., Beijing (CN)

(72) Inventors: Ruoli Dai, Beijing (CN); Haoyang Liu, Beijing (CN); Longwei Li, Beijing (CN); Jinzhou Chen, Beijing (CN); Baojia Gui, Beijing (CN)

(73) Assignee: Beijing Noitom Technology Ltd., Beijing (CN)

(21) Appl. No.: 15/505,923

(22) PCT Filed: Sep. 1, 2014
(86) PCT No.: PCT/CN2014/085659

§ 371 Date: Feb. 23, 2017

(51) Int. Cl. G01C 25/00; G06F 3/01; B81B 7/02; B81B 7/04

(52) U.S. Cl. CPC G01C 25/005; G06F 3/011; B81B 2201/0242; B81B 7/04; B81B 2201/0235; B81B 7/02

(57) ABSTRACT

A combined motion capturing system comprises multiple inertial sensor units (101), at least one communication unit (102), and a terminal processor (103). The inertial sensor units (101) are connected to the communication unit (102). The communication unit (102) is connected to the terminal processor (103). The inertial sensor units (101) are mounted at positions of one or more motion capture objects according to different combination modes, and measure motion information of the positions where the inertial sensor units (101) are mounted, and send the motion information to the communication unit (102). The communication unit (102) receives the motion information output by inertial sensors, and sends the motion information to the terminal processor (103). The terminal processor (103) acquires information about the motion capture objects and mounting position information of the inertial sensor units (101), generates combination modes of the inertial sensor units (101) according to the information of the motion capture objects and the mounting position information, receives the motion information sent by the communication unit (102), and processes the received motion information according to the combination modes to acquire complete postures and the motion information of the motion capture objects. By freely combining the same set of motion capturing devices, different motion capturing objectives are achieved, and the cost is reduced.

### TECHNICAL FIELD

The invention relates to motion capture technology, in particular to a combined motion capture system.

### BACKGROUND TECHNOLOGY

Motion capture technology can digitally record movements of an object. Currently, the commonly used motion capture technologies include optical-based motion capture and inertial-sensor-based motion capture, each being described below:

An optical-based motion capture system usually consists of four to thirty-two cameras, which are arranged around the object to be measured (hereinafter, the “motion capture object”). The key parts of the motion capture object are tagged with special light reflection points or light emitting points as marks for visual recognition and processing. After system calibration, the cameras continuously capture the movements of the object and store the series of captured images for analysis and processing, calculating the spatial location of each mark at any moment so that its accurate trajectory may be determined. The advantage of optical-based motion capture is that it does not require any mechanical device or cable, therefore allowing the object to move in a larger area. It also provides a much higher degree of sampling frequency. As such, it can meet the requirement for most motion capture tasks. But this system is expensive, its calibration process is very complex, and it can only capture the motions in the overlapping areas of the cameras. Furthermore, when the object's movement is complicated, the marks may easily block or be confused with each other, resulting in erroneous results.

Traditional mechanical inertial sensors have long been used in aircraft and ship navigation. With the rapid development of microelectromechanical system (MEMS) technology and the maturing of micro inertial sensor technology, people began to try to use micro inertial sensors in motion capture in recent years. The basic method is to attach inertial measurement units (IMU) to the motion capture object so that they can move along together. An inertial measurement unit usually includes a micro accelerometer (for measuring acceleration signal) and a micro gyroscope (for measuring angular velocity signal). By calculating the double integral of the acceleration signal and the integral of the gyroscope signal, we can get the object's location and orientation information. Due to the application of MEMS technology, the size and weight of an IMU can be made very small, therefore having minimal impact on the movement of the motion capture object. Also, inertial-sensor-based motion capture system has low site requirement, allows more moving space, and costs relatively low.

With the development of virtual reality technology, inertial-sensor-based motion capture technology has emerged as an important means of interaction. But current inertial-sensor-based motion capture systems are fixed. For example, an upper body motion capture system can only be used for capturing the movements of an upper part of a body. It cannot be adapted to capture movements of other parts of the body (such as lower body) by changing the mounting positions of the inertial sensors. Thus, if a user wants to change the measured part, he/she has to purchase additional motion capture systems or advanced systems with more inertial sensors, which will increase the cost.

### SUMMARY OF THE INVENTION

The invention provides a combined motion capture system, which achieves the purpose of different motion captures by the free combination of the same set of motion capture devices, therefore reducing cost.

The invention provides a combined motion capture system, which includes a plurality of inertial sensor units, at least one communication unit, and a terminal processor; the inertial sensor units are connected to the communication unit, respectively; and the communication unit is connected to the terminal processor; the inertial sensor units are mounted on various parts of one or more motion capture objects according to different combination modes, capture motion information of those parts, and transmit the motion information through wired or wireless communication means to the communication unit; the communication unit receives the motion information from the inertial sensor units and transmits the information to the terminal processor by wired or wireless communication means; the terminal processor obtains information regarding the motion capture object and mounting positions of the inertial sensor units, uses the information to generate a particular combination mode of the inertial sensor units, receives motion information from the communication unit, and processes the received motion information according to the combination mode to obtain the complete posture and motion information of the object.

In one embodiment, the motion information includes location and orientation information; in another embodiment, the motion information includes location and orientation information and inertial information such as acceleration information, angular velocity information, etc.

In one embodiment, the terminal processor is used to: obtain information regarding the motion capture object and the mounting positions of the inertial sensor units, retrieve an object model already stored in a memory or create a new object model based on the information regarding the object, use the object model and mounting position information to generate a particular combination mode of the inertial sensor units, receive motion information from the communication unit, and process the received motion information according to the combination mode to obtain the complete posture and motion information of the object.

In one embodiment, the terminal processor is used to: correct the location and orientation of the inertia sensor units according to mechanical constraints of the motion capture object, e.g., correct the object's location, orientation, and displacement to avoid the occurrence of reversed joint or ground contact puncture, estimate the location, orientation, and motion of those parts of the object where no inertia sensor unit is mounted with method such as using inertial sensor modules adjacent to those parts to perform interpolation-type estimation according to the motion characteristics of those parts.

In one embodiment, the inertial sensor unit includes:

the sensor module, including: three-axis MEMS accelerometer, three-axis MEMS gyroscope, and three-axis MEMS magnetometer, which measure the acceleration, angular velocity, and magnetic signal of the part where the inertial sensor unit is mounted, respectively;

the first microprocessor module, which is connected to the sensor module and calculates the location and orientation information of the part where the inertial sensor unit is mounted based on the measured acceleration, angular velocity, and magnetic signal;

the first communication module, which is connected to the first microprocessor module and is used for transmitting the motion information, such as location and orientation information, inertial information, etc.

In one embodiment, the communication unit comprises: a second microprocessor module, a second communication module and a third communication module, and the second communication module and the third communication module are connected to the second microprocessor module, respectively.

In one embodiment, the communication unit further includes a battery and a direct current to direct current (hereinafter “DC/DC”) conversion module; the first communication module is connected to the second communication module via a wired serial communication connection, and the third communication module is connected to the terminal processor via a wireless communication connection.

In one embodiment, the inertial sensor unit further includes a battery and a DC/DC conversion module; the first communication module is connected to the second communication module via a wireless communication connection, and the third communication module is connected to the terminal processor via a wired serial communication connection.

In one embodiment, the communication unit further includes a first battery and a first DC/DC conversion module, and the inertial sensor unit further includes a second battery and a second DC/DC conversion module; the first communication module and the second communication module are connected via a wireless communication connection, and the third communication module is connected to the terminal processor via a wireless communication connection.

In one embodiment, the first communication module and the second communication module are connected via a wired serial communication connection, and the third communication module is connected to the terminal processor via a wired serial communication connection; the communication unit further includes DC/DC conversion module.

In one embodiment, the first microprocessor module is used to calculate the integral of the angular velocity information, generate dynamic spatial location and orientation, generate static absolute spatial location and orientation based on the acceleration and the geomagnetic vector, and adjust the dynamic spatial location and orientation based on the static absolute spatial location and orientation to generate the location and orientation information.

In one embodiment, various parts of each of the plurality of motion capture objects include various parts of a human body, an animal, and/or a robot.

In one embodiment, the inertial sensor unit is mounted on different motion capture objects at different times.

In one embodiment, when a user uses the combined motion capture system for the first time or changes the combination mode of the inertial sensor units or mounting positions of the units, the terminal processor is also used to specify the combination mode and mounting positions of the inertial sensor units.

In one embodiment, when the inertial sensor unit is transferred from one motion capture object to another, the terminal processor is used to change the object model or create a new object model.

In one embodiment, after the inertial sensor unit is installed, the terminal processor is also used to calibrate the action according to the combination mode and the motion capture object, to correct the installation error of the inertial sensor unit.

The benefit of the present invention is that a plurality of inertial sensor units of the invention may be mounted onto a motion capture object in various different combination modes. The inertial sensor units may also be mounted onto different kinds of motion capture object in various combination modes. Through flexible combination modes of the same set of motion capture equipment, the present invention can achieve different motion capture objectives, and therefore reducing cost.

### DESCRIPTION OF DRAWINGS

In order to more clearly illustrate the embodiments of the present invention or the technical solution in existing technologies, the drawings that are needed in the description of the embodiments and existing technologies will be briefly described below. Obviously, the drawings in the following description are only some embodiments of the present invention, and those skilled in the art can obtain other drawings based on these drawings without exercising any creative effort.

FIG. 1 is a schematic diagram of a combined motion capture system according to one embodiment of the present invention.

FIG. 2 is a schematic diagram of a combined motion capture system according to one embodiment of the present invention.

FIG. 3 is a schematic diagram of a combined motion capture system according to one embodiment of the present invention.

FIG. 4 is a schematic diagram of a combined motion capture system according to one embodiment of the present invention.

FIG. 5 is a schematic diagram of a combined motion capture system according to one embodiment of the present invention.

FIG. 6 is a flow chart of the combined motion capture system according to one embodiment of the present invention.

### SPECIFIC IMPLEMENTATION

The technical solutions in each embodiment of the present invention are clearly and completely described below in combination with the relevant drawings. Obviously, the described embodiments are only part, not all, of the embodiments of the present invention. Based on the embodiments described below, those skilled in the art can obtain other embodiments of the present invention, which are also within the protected scope of the present invention.

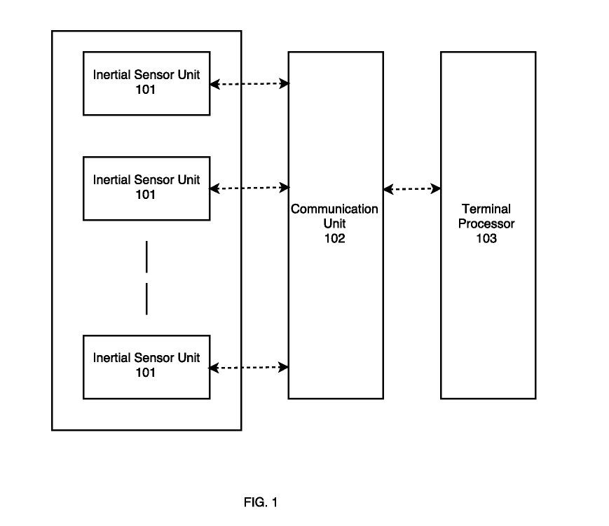

As shown in FIG. 1, the invention provides a combined motion capture system, which comprises a plurality of inertial sensor units 101, at least one communication unit 102 and a terminal processor.

The plurality of inertial sensor units 101 are respectively connected to the communication unit 102 in a wired or wireless manner, and the communication unit is connected to the terminal processor 103 in a wired or wireless manner.

The plurality of inertial sensor units 101 are mounted on various parts of one or more motion capture objects according to different combination modes. There may be multiple types of motion capture objects, such as human body, robots, and animals. Various types of mounting methods may be used. For example, gloves, wearables, or sensor clothes may be used to mount the sensor units onto hands or other parts of a body. The plurality of inertial sensor units 101 measure the motion information (e.g., location, orientation, acceleration, angular velocity) of the various body parts and transmit the motion information to the communication unit 102 via wired or wireless communication means.

The communication unit 102 receives the motion information from the plurality of inertial sensor units 101 via wired or wireless communication means and sends the motion information to the terminal processor 103 via wired or wireless communication means.

The terminal processor 103 obtains information regarding the motion capture object and information regarding the mounting positions of the plurality of inertial sensor units 101, and use that information to generate a particular combination mode of the inertial sensor units, receives motion information from the communication unit, processes the received motion information according to the combination mode to obtain the complete posture and motion information of the object.

During operation, the terminal processor 103 can obtain information regarding the motion capture object and the mounting positions of the plurality of inertial sensor units 101. The terminal processor 103 retrieves an object model already stored in a memory or creates a new object model based on the information regarding the object, and uses the object model and mounting position information, specified by the user or detected by the system, to generate a particular combination mode of the inertial sensor units 101. It receives motion information from the communication unit 102, and processes the received motion information according to the combination mode to obtain the complete posture and motion information of the object.

In one embodiment, the terminal processor 103 processes the received motion information according to the combination mode to obtain the complete posture and motion information of the object by using the following method: revise the movement of the inertial sensor units 101 according to mechanical constraints of the motion capture object, e.g., adjust the object's location, orientation, and displacement based on joint or ground contact constraint; determine the location, orientation, and motion of those parts of the object where no inertial sensor unit is mounted by method such as using inertial sensor modules adjacent to those parts to do interpolation type estimation. For example, the location, orientation and movement of a spine may be estimated via interpolation based on the motions of the hip and chest. Estimation may also be implemented based on the characteristics of the object's motion and the parent node's motion. For example, the position and motion of toes should follow those of the sole without any external contact. When the toes are touching the ground, the direction of the toes should be consistent with the direction of the sole, but its angle should be parallel to the contact surface.

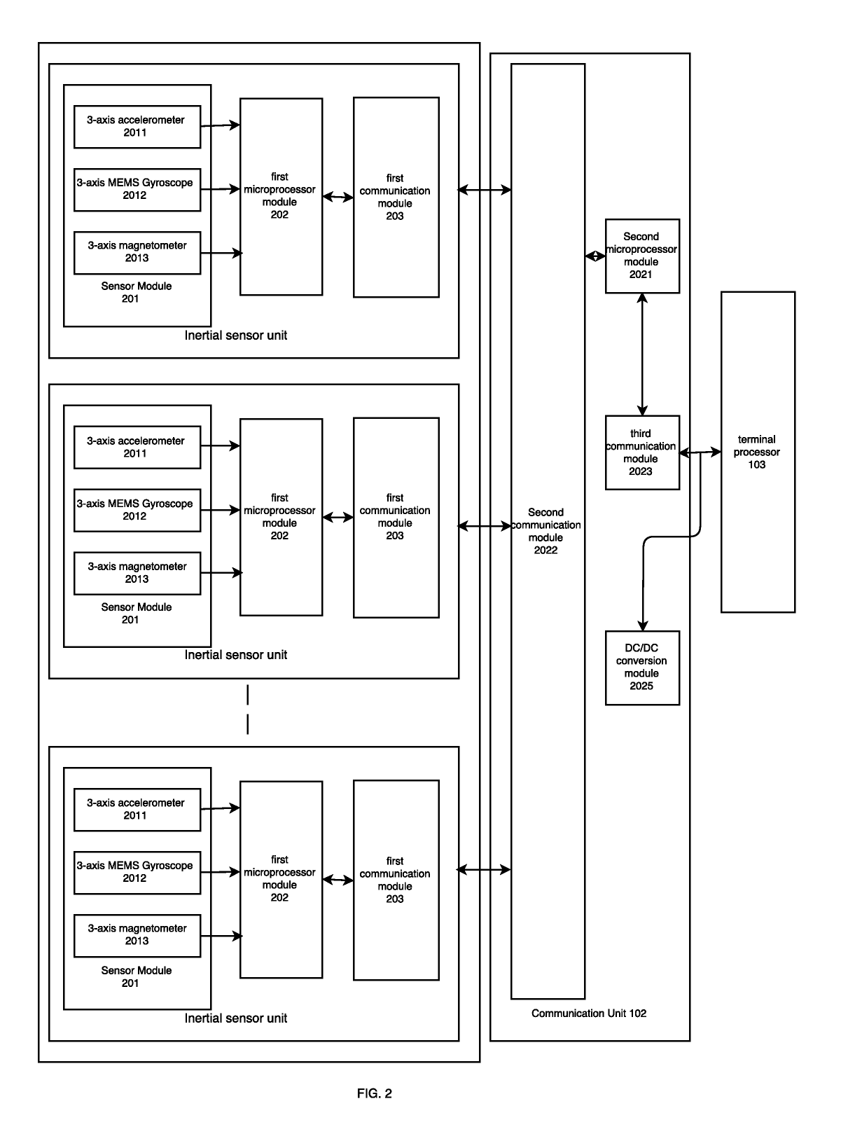

As shown in FIG. 2 to FIG. 5, the specific embodiments of the invention, the combined motion capture system's inertial sensor unit 101 includes a sensor module 201, a first processor module 202 and a first communication module 203.

The sensor module 201 includes a three-axis MEMS accelerometer 2011, a three-axis MEMS gyroscope 2012 and a MEMS magnetometer 2013. Three-axis MEMS accelerometer 2011 measures the acceleration signal of the part where the inertial sensor unit 101 is mounted. The three-axis MEMS gyroscope 2012 measures the angular velocity signal of the part where the inertial sensor unit 101 is mounted. The three-axis MEMS magnetometer 2013 measures the magnetic signal of the part where the inertial sensor unit 101 is mounted.

The first microprocessor module 202 is connected to the sensor module 201 in the same inertial sensor unit 101. It calculates the location and orientation of the part where the inertial sensor unit 101 is mounted based on the acceleration signal, angular velocity signal and magnetic signal received from the sensor module 201.

In one embodiment, the first microprocessor module 202 is specifically used for calculating the integral of the angular velocity information, generating the dynamic spatial location and orientation, calculating the static absolute spatial location and orientation according to the acceleration information and the geomagnetic vector, and using the static absolute spatial location and orientation to adjust the dynamic spatial location and orientation to generate the location and orientation information.

The first communication module 203 is connected to the first microprocessor module 202 to send the obtained motion information (such as location and orientation information, acceleration information, angular velocity information, etc.) to the communication unit 102.

As shown in FIG. 2 to FIG. 5, the specific embodiments of the invention, the communication unit 102 of the combined motion capture system comprises: a second microprocessor module 2021, a second communication module 2022 and a third communication module 2023. The second communication module 2021 and the third communication module 2022 are respectively connected to the second microprocessor module 2023. The second microprocessor module 2021 controls the second communication module 2022 to receive motion information from each inertial sensor unit 101, package the motion information, and transmit the package to the terminal processor 103 via the third communication module 2023.

The first communication module 203 and the second communication module 2022, and the terminal processor 103 and the third communication module 2023 can all be connected via wireless communication means or wired serial communication means. Or, the first communication module 203 and second communication module 2022 may be connected via wireless communication means, whereas the terminal processor 103 and the third communication module 2023 may be connected via wired serial communication means. Or, the first communication module 203 and second communication module 2022 may be connected via wired serial communication means, whereas the terminal processor 103 and the third communication module 2023 may be connected via wireless communication means. The above connection modes are described below.

In one embodiment, as shown in FIG. 2, the first communication module 203 and the second communication module 1022 are connected via a wired serial communication connection, and the third communication module 2023 is connected to the terminal processor 103 via a wired serial communication connection. The first communication module 203, the second communication module 1022 and the third communication module 2023 are all serial communication module. The communication unit 102 further includes a DC/DC conversion module 2025 to obtain power from the terminal processor 103 through a wired connection, and to provide power to the communication unit and all inertial sensor units after the DC/DC conversion. The first communication module 203, the second communication module 2022 and the third communication module 2023 are all serial communication modules.

The combined motion capture system comprises a plurality of inertial sensor units 101, a communication unit 102 and a PC working as a terminal processor 103.

The inertial sensor unit 101 includes a sensor module 201, a first microprocessor module 202 and a first communication module 203. The sensor module 201 includes a three-axis MEMS accelerometer 2011, a three-axis MEMS gyroscope 2012 and a MEMS magnetometer 2013 for measuring the acceleration, angular velocity and magnetic signal, respectively.

The first microprocessor module 202 receives the acceleration, angular velocity and magnetic information from the sensor module 201 and calculates the spatial location and orientation information of the sensor module 201. The first communication module 203 sends the motion information to the communication unit 102 via a wired connection. The communication unit 102 comprises a second microprocessor module 2021, a second communication module 2022, and a third communication module 2023. The communication unit 102 receives motion information from each inertial sensor unit 101 via the second communication module 2022, packages the motion information with the second microprocessor module 2021, and transmits the package to the terminal processor 103 via the third communication module 2023.

Through wired connection, the communication unit 102 obtains power from the terminal processor 103 and, after DC/DC conversion of the power, supplies the converted power to the communication unit 102 and all inertial sensor units connected to it. The terminal processor 103 receives the motion information of the inertial sensor unit 101, executes corresponding process and calculation according to an object model specified via software interface and the mounting position of the inertia sensor unit 101, including correcting the motion information of the inertial sensor units 101 according to mechanical constraints on the motion capture object and estimating the location and motion of those parts of the object where no inertial sensor unit is installed. The terminal processor 103 may display the calculated results via real-time animation or store the results in a particular data format or transmit them via network.

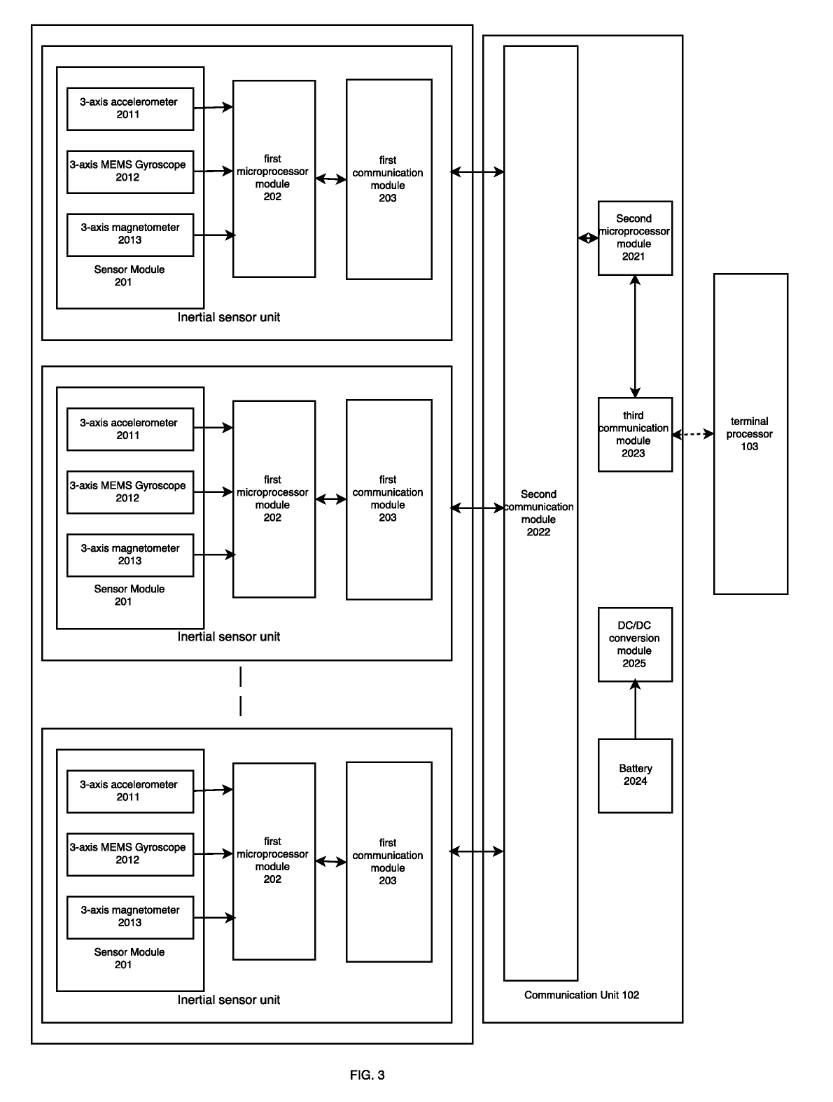

In one embodiment, as shown in FIG. 3, the first communication module 203 and the second communication module 2022 are connected through a wired serial communication connection; the third communication module 2023 is connected to the terminal processor 103 via wireless communication. The second microprocessor module 2021 receives motion information from each inertial sensor unit 101 through the second communication module 2022, and then packages them and transmits them to the terminal processor unit 103 through the third communication module 2023 (RF communication module). Compared with FIG. 2, the communication unit 102 of FIG. 3 further comprises a battery 2024 and DC/DC conversion module 2025, the battery 2024 performing the DC/DC conversion via the DC/DC conversion module 2025 and supplying power to the communication unit 102 and all the inertial sensor units 101. The third communication module 2023 may be an RF communication module or other type of module that can wirelessly communicate with the terminal processor 103. The first communication module 203 and second communication module 2022 are serial communication modules. Through wired connection between the communication unit 102 and the inertia sensor unit 101, the battery 2024 may also supply power to each part of the inertial sensing unit 101.

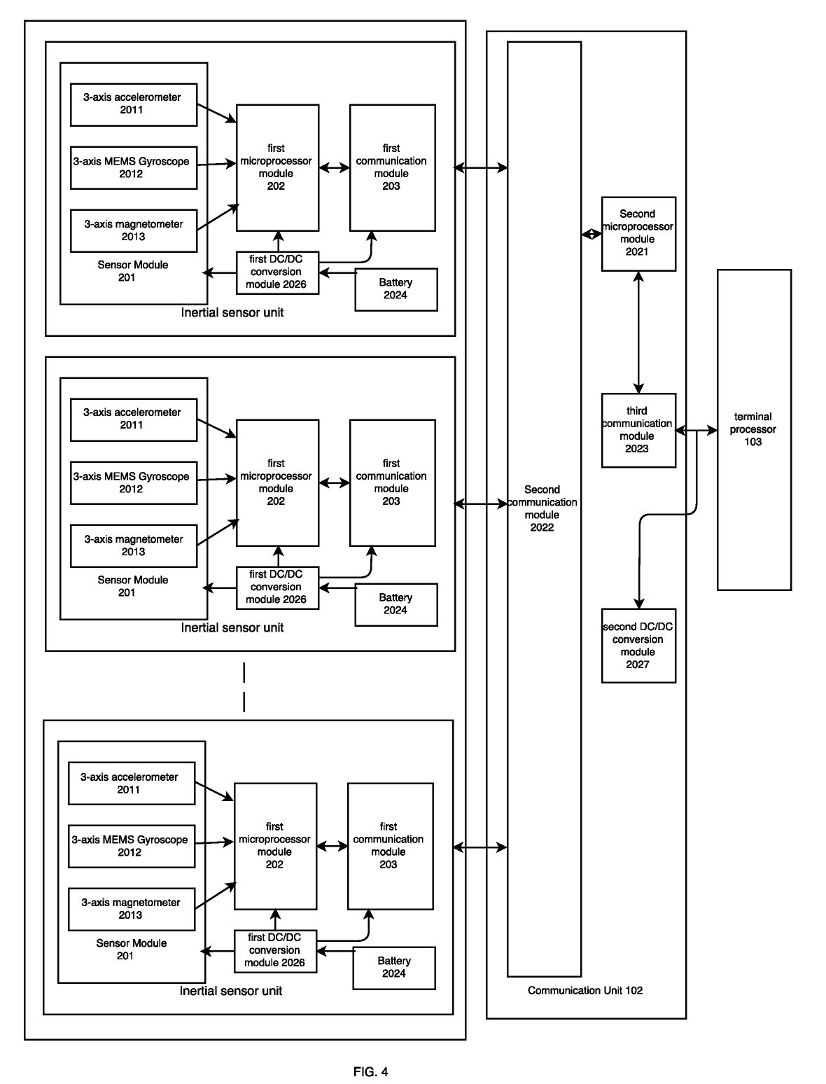

In one embodiment, as shown in FIG. 4, the first communication module 203 and the second communication module 2022 are connected via wireless communication, and the third communication module 2023 is connected to the terminal processor 103 via wired serial communication connection. In this embodiment, the inertial sensor unit 101 further comprises a battery 2024, a first DC/DC conversion module 2026, which performs DC/DC conversion on the electric power of battery 2024. The communication unit 102 further comprises a second DC/DC conversion module 2027, and through wired connection between the communication unit 102 and the terminal processor 103, the terminal processor 103 may supply power to the communication unit 102. The second DC/DC conversion module 2027 can perform DC/DC conversion on power supplied from the terminal processor 103 and supply the converted power to the communication unit 102. The first communication module 203 and the second communication module 2022 may be RF communication modules or other type of module that can wirelessly communication the terminal processor 103. The third communication module 2023 is a serial communication module.

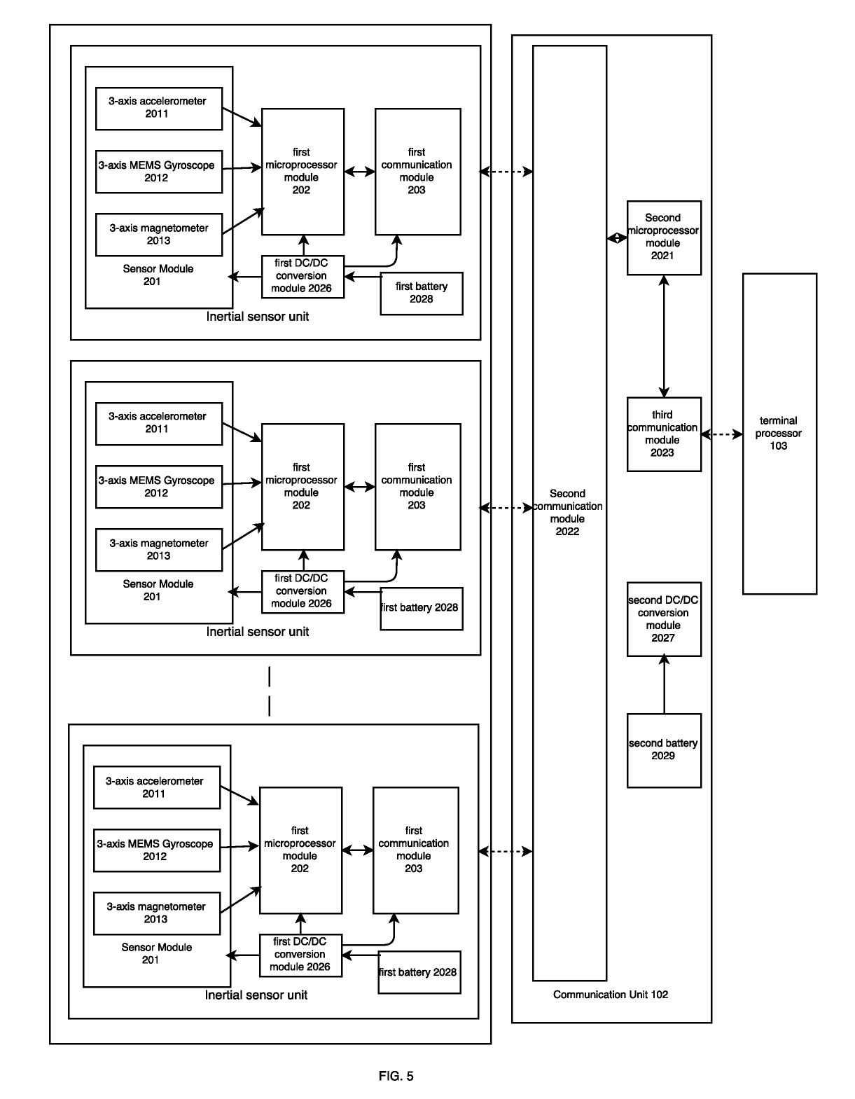

In one embodiment, as shown in FIG. 5, a communication unit 102 further includes a first battery 2028 and a first DC/DC conversion module 2026. The inertial sensor unit 101 further comprises a second battery 2029 and a second DC/DC conversion module 2027. The first communication module 203 and the second communication module 2022 are connected via wireless communication means, and the communication module 2023 is connected to the terminal processor 103 via wireless communication means. The first communication module 203, the second communication module 2022 and the third communication module 2023 may be RF communication modules or other types of modules that can wirelessly communicate with the terminal processor 103.

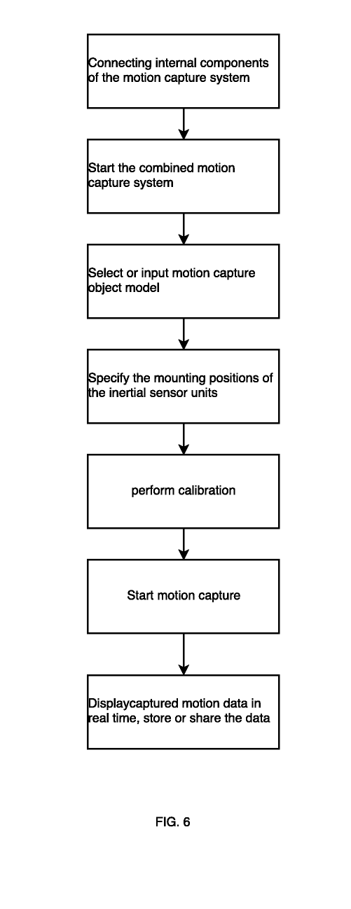

FIG. 6 is a flow chart of the combined motion capture system of the present invention. As shown in FIG. 6, firstly, the inertial sensor unit 101 is connected to the motion capture object through sensor suit, belt, glove, adhesive tape, etc. to establish the physical connection with each part. Then, the combined motion capture system is started, and corresponding software on the terminal processor 103 is launched to establish software connections. Next, an object model is selected from the software interface based on information regarding the motion capture object and the mounting position of the inertial sensor unit 101. If the software does not contain the corresponding object model, the user can manually create or input an object model, which includes the connection relation of each part of the object and the size and initial orientation of each part. For the object model, constraint and limit between the respective parts can also be set or modified, such as allowed joint movement angle. After determining the object model, according to the actual mounting position of the sensor unit, the position of each sensor is specified on the software interface of the terminal processor and the specified position should be consistent with the actual position. After determining the mounting position of each sensor unit, the installation error of each sensor needs to be calibrated. Calibration can be achieved by following the existing calibration actions in the software, or by following calibration actions specified and designed by a user. During calibration, the motion capture object shall perform the calibration action according to the posture specified on the software interface. The receiving processor determines the installation error of the sensor unit according to the known posture and the motion information measured by the sensor unit. After the calibration, the system can start capturing the motion of the motion capture object. During motion capture, the inertial sensor unit 101 sends location, orientation and other motion information of the part where the sensor is mounted to the communication unit 102 via wired or wireless communication connection. The, the communication unit 102 packages such information and transmits the package to the terminal processor 103 via a wired or wireless connection. The terminal processor 103 corrects the measured motion information, such as orientation and displacement, to meet the joint constraint or external contact constraints, and estimates the movement of those parts where no sensor is mounted by, for example, interpolating the motion information of adjacent parts. Then, the complete location, orientation and other motion information of each part of the object is mapped onto the object model so that the object model can follow the movement of the actual object. The terminal processor 103 can display the motion data of the motion capture in real time, store the data locally, or share it via network.

In one embodiment, the inertial sensor unit 101 may be installed on different motion capture object at different time. When a user uses the combined motion capture system for the first time or changes the combination mode or mounting position of the inertial sensor unit 101, the terminal processor 103 is further used for specifying the combination mode and mounting position of each inertial sensor unit 101. After determining the object model, according to the actual mounting position of the inertia sensor unit 101, the mounting position of each sensor is specified on the software interface of the terminal processor 103, and the specified position must be consistent with the actual position.

In one embodiment, when the inertial sensor unit 101 is transferred from one motion capture object to another, the terminal processor 103 is also used to modify the motion capture object model or create a new model. When selecting object model from the software interface on the terminal processor, if the software does not include the object model, a user can manually create or input the object model, which includes the connection relation of each part of the object and the size and initial orientation of each part.

The benefit of the present invention is that a plurality of inertial sensor units of the invention can be mounted onto a motion capture object in various different combination modes. The inertial sensor units can also be mounted onto different kinds of motion capture the object in various combination modes. Through flexible combination modes of the same set of motion capture equipment, the present invention can achieve different motion capture objectives, and therefore reducing cost.

In order to better illustrate the present invention, the present invention will be described below in conjunction with a specific embodiment.

(1) A Combined Virtual Reality Game System Based on Inertial Sensor Units.

In this embodiment, the combined motion capture system comprises ten inertial sensor units, a communication unit, a tablet computer (working as the terminal processor; it may also be a PC) and a head-mounted virtual reality display. The ten inertial sensor units are combined according to the specific need for the virtual reality game; so the same system can be used for different types of virtual reality games.

In this embodiment, let's assume that a user is playing a game of throwing dart with friends in the virtual environment. The user first needs to mount the ten sensor units to each finger (two thumbs, one for each of the four remaining fingers), back of the hand, upper arm, lower arm and chest. The inertial sensor units can be mounted to the hand via a flexible glove, and the sensor units for the remaining parts can be mounted by bandage. Each inertial sensor unit is connected to the communication unit mounted onto the chest via wired communication connections. The communication unit is connected to the tablet computer via a wired connection. Each inertial sensor unit measures the location and orientation of the part where it is mounted and sends the result to the communication unit via wired serial communication connection. The communication unit transmits the received location and orientation information to the tablet computer via a USB interface and obtains power from the tablet computer via the USB interface. The tablet computer is connected to the communication unit via the USB interface, and is connected to the head-mounted virtual reality display device via a HDMI interface. The tablet computer is connected to a virtual reality scene on the network server. The network server sends the real-time scene information and scene change information to the tablet computer via network. And the tablet computer sends such virtual reality scene information to the head-mounted virtual reality display device via the HDMI interface. The tablet computer receives the location and orientation information regarding the hand, the arm, and the chest, processes the information to obtain the posture information of the hand and chest. The tablet computer imposes the motion information of the hand and chest onto the virtual character corresponding to the wearer (i.e., the user wearing the sensors); and the virtual character's hand and upper body will move in sync with the wearer's movement. The implementation process of this embodiment will be described in detail.

To start using the system, firstly, each inertial sensor unit is mounted to the hand, arm and chest through a glove and bandages and all parts are connected; then, the motion capture software on the tablet computer is launched, and the installation error of each inertial sensor is calibrated. The calibration method is that the wearer should perform one or two known gestures, such as a T-pose with five fingers are closed together. The installation error for each inertial sensor unit can be determined based on the measured location and orientation information of each sensor unit at the known posture.

Next, the network is connected to the virtual reality server of the dart throwing game. After successful connection, a client-side software application on the tablet computer will generate a virtual character—a user may custom order the virtual character. There are virtual darts next to the virtual character. Opposite to the virtual darts is a virtual target. The wearer can use hand to grasp a virtual dart to throw at the virtual target. The head-mounted display can send the head's location and orientation to the tablet computer. After the tablet computer receives the virtual scene information and the location and orientation information of the head-mounted virtual reality display, it generates visual image information corresponding to the visual perspective based on the head's position and orientation and sends the image information to the head-mounted virtual reality display. Besides the virtual target next to the wearer, there may be multiple virtual targets in the virtual scene. Thus, the system allows multiple users and friends to play in the same virtual scene, and they can vocally communicate via microphones and earphones of the tablet computer.

Each inertial sensor unit measures the local gravity vector via a three-axis MEMS micro-accelerometer and the local geomagnetic vector via a MEMS magnetometer. The first microprocessor of the inertial sensor unit can calculate the static absolute three-dimensional posture angle of the inertial sensor unit based on the gravity vector and the magnetic vector. Each inertial sensor unit measures the angular velocity via a three-axis MEMS gyroscope, and the first microprocessor can calculate dynamic three-dimensional posture angle of the unit. The final location and orientation information of the inertial sensor unit may be obtained based on actual movement of the inertial sensor unit in combination with the static absolute three-dimensional posture angle and the dynamic three-dimensional posture angle.

An inertial sensor unit communication module is connected to the ten inertial sensor units by means of serial communication and obtains the measured location and orientation information of each sensor unit in a rotating manner. The communication module then packages the motion information and transmits it to the tablet computer.

After the tablet computer receives the location and orientation information of each part from the communication unit, it processes the information to obtain the orientation and movement of the arm and chest. The processing of the location and orientation information includes adjustment based on the biomechanics restraints of hand, for example, correction of location and orientation according to the finger-joint constraints to prevent reverted joint situation, and estimation of the position and orientation of those parts where no sensor is mounted. For example, to estimate a finger tip's position and orientation, we could consider that its position and angle relative to the figure's middle joint are equal to the position and angle of the middle joint relative to the finger's root joint.

After the tablet computer receives the motion information of the whole hand and the chest, it maps the information to the corresponding part of the virtual character, such that the movement of the virtual character in the virtual scene follows the motion of the wearer. Through the head-mounted virtual reality display and the movement of the wearer's hand, the wearer can grasp and throw a dart in a virtual scene.

After enjoyed the dart throwing game, the user can play a different virtual reality game, such as virtual reality shooting game. At this time, the wearer exits the dart game scene, takes off the inertial sensor units from the fingers, and mounts the sensor units to other parts of his body via wearable cloth. Now the ten inertial sensor units can be mounted to the head, chest, hip, two upper arms, lower arms, and hand backs and the toy gun. Then, the user needs to designate the corresponding sensor unit on the motion capture software interface on the tablet computer. Next, the user uses his right hand (or left hand) to hold the toy gun and poses in a specified posture (such as T-posture) as a calibration action. After the calibration, the tablet computer is connected to the virtual reality scene, starting the real-time virtual reality shooting game.

During the virtual reality shooting game, the inertial sensor units measure the location and orientation information of the toy gun and the user's upper body in real time and transmit such information to the tablet computer via the communication unit. The tablet computer processes such information to obtain the body's corresponding motion information and map the motion information onto the virtual character in the virtual reality scene, such that the virtual character moves in sync with the movement of the user. The signal of pulling the toy gun's trigger is transmitted to the tablet computer via RF signals of the toy gun such that the virtual gun fires in response to the trigger pulling action in the virtual reality scene, bring the player an immersive experience of the shooting game.

This embodiment is a combination on a same motion capture object (such as a human). It is an implementation plan for a low cost combined virtual reality game. Using fewer inertial sensor units, and via different combination mode of the units, users can experience a variety of different virtual reality games with low investment.

(2) Multi-Object Combined Motion Capture Application Example

This implementation of the combined motion capture system comprises thirty inertial sensor units, three RF communication units, and one terminal processor. The inertial sensor units communicate with the RF communication unit via wired serial communication connection, and the RF communication unit communicates with the terminal processor via Wi-Fi connection. The multi-object combined motion capture implementation may be used in a plurality of application cases. It can form three sets of independent ten-sensor based upper body motion capture systems, each set of system comprising an RF communication unit and ten inertial sensor units, and the three sets of upper body motion capture systems may connect to the same terminal processor, achieving multi-person motion capture. The combination of the present invention may also be in the form of a set of full body (with fingers of both hands) system with a tool for implementing the complete capture of a single person's full body motions. It also can be used on a non-human object, such as capturing the movement of a cat and so on. The implementation of this embodiment is described below.

An application of this implementation is a three-person virtual reality game. The implementation process is as follows: mounting the thirty inertial sensor units and the three communication units on the three persons' upper bodies, respectively; each person's upper body and tool have ten inertial sensors mounted in total and a Wi-Fi communication unit is mounted on the person's back; each person's sensors are connected to the person's Wi-Fi communication unit via wired communication connection; the Wi-Fi communication unit packages the motion information received from each inertial sensor and transmits the package to the terminal processor (computer) via Wi-Fi communication connection. After finishing mounting the inertial sensor units and the communication unit, the system is started and three human models are created via the interface on the computer, each model corresponding to a person. The mounting positions of all sensor units are specified on the interface. Then, beginning the calibration, three users perform a calibration action (such as T-posture) simultaneously to correct installation errors, and then the movement of each person is captured. The three persons can connect to the same computer to play the virtual reality game via their head-mounted virtual reality displays and tools.

Another combination mode in this embodiment is to mount all thirty inertial sensor units on the body of the same person, including both hands and the full body. Motion information captured by the inertia sensor units is communicated to a Wi-Fi communication unit through a wired serial communication connection and then is transmitted to the computer by the Wi-Fi communication unit. After mounting and connecting the inertial sensor units and the Wi-Fi communication unit, the motion capture software is started on the computer. Only one human model is used on the software interface, and the mounting position of each inertial sensor unit is specified on the interface. Then, the mounting position of each sensor can be calibrated by, for example, posing the T-pose with both hands folded with the palm pointing down, a natural standing posture and so on. After the calibration is finished, the motion of the person's whole body can be captured.

In a different combination mode of this embodiment, sixteen inertial sensor units in the system are mounted on the body of a cat. The mounting positions of the sensors include head, neck, shoulder, waist, hip, tail (three units), the upper and lower legs of the four legs. The inertial sensor units send the captured motion signals to the Wi-Fi communication unit mounted on the cat's waist via wired serial communication connection. Before mounting the sensors, a cat model shall be created on the interface of the motion capture software, including inputting the size for each part of the cat and the cat's initial posture. After the sensors are installed, the specific mounting position of each sensor unit shall be specified in the software interface. Then a calibration posture is provided according to the characteristics of the cat (the posture is relatively common and the orientation of each part is known), and then have the cat makes specified calibration action through human petting (if the action is not accurate, recalibration is needed). After the calibration, the cat's movements can be captured.

Besides the above combination modes, the embodiment can also be applied to capture the movement of any object with multiple joints.

The same set of motion capture system can capture the simultaneous movement of multiple objects and movement of different types of objects.

Those skilled in the art shall appreciate that the embodiments of the invention can be embodied as a method, system, or computer program product. Therefore, the invention can adopt all hardware embodiments, entirely software embodiments, or in the form of software and hardware in combination. Furthermore, the invention can be implemented in the form of a computer program product using one or more computer usable storage medium including computer executable program code (including but not limited to a disk memory, CD-ROM, optical memory, etc.).

The invention is described with reference to the flow charts and block diagrams of the method, device (system) and the computer program product. It should be understood that each flow and/or block in the flow charts and/or block diagrams and combinations of the flows and/or blocks may be realized by computer program instructions. These computer program instructions can be loaded onto a general-purpose computer, a specific-purpose computer, an embedded processor or a processor of another programmable data processing device to produce a machine, such that the computer or the processor of the other programmable data processing device may execute the instructions to achieve the functions specified in the one or more blocks in a block diagram.

These computer program instructions may also be stored in a computer readable memory capable of directing the computer or the other programmable data processing device to operate in a specific manner so that the instructions stored in the computer readable memory create an article of manufacture including instruction device, and the instruction device realizes functions specified in one or more of the flows in the flow chart and/or one or more blocks in the block diagrams.

These computer program instructions can also be loaded onto the computer or the other programmable data processing device so that the computer or the other programmable device performs a series of operational steps to create a computer implemented process so that the instructions executed on the computer or the other programmable device achieves one or more functions specified in the one or more flows of the flow charts and one or more blocks of the block diagrams.

The above embodiments are used for describing the principle and implementation of the present invention. They are used for understanding the method and core principle of the present invention. And, to those skilled in the art, following the core principle of the present invention, the specific implementation and application may change. In sum, the specification shall not be a limit to the scope of this invention.

1. A combined motion capture system, comprising:
a plurality of inertial sensor units,
at least one communication unit, and
a terminal processor, wherein the plurality of inertial sensor units are connected to said at least one communication unit respectively, said at least one communication unit is connected to the terminal processor, and each inertial sensor unit is mounted on one of a plurality of parts of one or more motion capture objects according to different combination modes of the plurality of inertial sensor units to measure motion information of said plurality of parts and transmits the motion information via a wired or wireless communication connection to the communication unit, and wherein the communication unit receives the motion information from the plurality of inertial sensor units and transmits the motion information to the terminal processor via a wired or wireless communication connection, and wherein the terminal processor obtains information regarding the one or more motion capture objects and mounting positions of the plurality of inertial sensor units and generates a combination mode of the plurality of inertial sensor units based on said information regarding the one or more motion capture objects and said mounting positions of the plurality of inertial sensor units, the terminal processor receiving the motion information transmitted by the communication unit and processing the motion information according to the combination mode to obtain complete posture and motion information of the one or more motion capture objects.

2. The combined motion capture system according to claim 1, wherein said terminal processor is specifically used for: obtaining said information regarding the one or more motion capture objects and said mounting positions of the plurality of inertial sensor units, retrieving an object model already stored in a memory or creating a new object model according to said information regarding the one or more motion capture objects, generating said combination mode of the plurality of inertial sensor units based on said retrieved object model or new object model and said mounting positions of the plurality of inertial sensor units, receiving said motion information from said communication unit, and processing said motion information according to said combination mode to obtain the complete posture and motion information of the one or more motion capture objects.

3. The combined motion capture system according to claim 1, wherein said terminal processor is specifically used for: correcting said motion information from the plurality of inertial sensor units according to mechanical restraints of the one or more motion capture objects, and estimating positions, orientations, and movements of those parts where no inertial sensor unit is mounted.

4. The combined motion capture system according to claim 1, wherein each of the plurality of inertial sensor units comprises: a sensor module comprising a three-axis MEMS accelerometer, a three-axis MEMS gyroscope, and a three-axis MEMS magnetometer for measuring acceleration, angular velocity, and magnetic signals of the corresponding part where the corresponding inertial sensor unit is mounted; a first microprocessor module connected to the sensor module, calculating position and orientation of said corresponding part according to the acceleration, angular velocity, and magnetic signals; and a first communication module connected to the first microprocessor module for transmitting the motion information.

5. The combined motion capture system according to claim 4, wherein the communication unit comprises a second microprocessor module, a second communication module, and a third communication module, the second communication module and the third communication module are connected to the second microprocessor module respectively.

6. The combined motion capture system according to claim 5, wherein the communication unit further comprises a battery and a DC/DC conversion module, the first communication module and the second communication module is connected via a wired serial communication connection, and the third communication module is connected to the terminal processor via a wireless communication connection.

7. The combined motion capture system according to claim 5, wherein said corresponding inertial sensor unit further comprises a battery and a DC/DC conversion module, the first communication module and the second communication module are connected via a wireless communication connection, and the third communication module is connected to the terminal processor via a wired serial communication connection.

8. The combined motion capture system according to claim 5, wherein the communication unit further comprises a first battery and a first DC/DC conversion module, said corresponding inertial sensor unit further comprises a second battery and a second DC/DC conversion module, the first communication module and the second communication module are connected via a wireless communication connection, and the communication module is connected to the terminal processor via a wireless communication connection.

9. The combined motion capture system according to claim 5, wherein the first communication module and the second communication module are connected via a wired serial communication connection, the third communication module is connected to the terminal processor via a wired serial communication connection, and the communication unit further comprises a DC/DC converting module.

10. The combined motion capture system according to claim 4, wherein said first microprocessor module is specifically used for calculating an integral of the angular velocity information to generate a dynamic spatial position and orientation, generating a static absolute spatial position and orientation based on said acceleration information and geomagnetic vector, and correcting the dynamic spatial position and orientation using the static absolute spatial position and orientation, and generating the position and orientation.

11. The combined motion capture system according to claim 1, wherein the plurality of parts of the one or more motion capture objects comprises parts of a human, an animal, or a robot.

12. The combined motion capture system according to claim 1, wherein the inertial sensor units are mounted on different motion capture objects at different times.

13. The combined motion capture system according to claim 2, wherein, when a user first uses the combined motion capture system or changing the combination mode or the mounting positions of the plurality of inertial sensor units, the terminal processor is further used for specifying the combination mode and mounting positions of the plurality of inertial sensor units.

14. The combined motion capture system according to claim 2, wherein, when the plurality of sensor units is transferred from one motion capture object to another motion capture object, said terminal processor is further configured to change the object model or create a new object model.

15. The combined motion capture system according to claim 2, wherein, after mounting the plurality of inertial sensor units, the terminal processor is further used for calibration according to the combination mode and the motion capture object so as to correct installation errors of the plurality of inertial sensor units.
